(19) United States
(12) Patent Application Publication
(10) Pub. No.: US 2005/0113948 A1
(43) Pub. Date: May 26, 2005

(54) Digital-to-analog audio conversion

(76) Inventor: Christopher Su-Yan Own, Evanston, IL (US)

Correspondence Address: Reece Nienstadt, 3945 Connecticut Avenue, N.W., Apt. 104, Washington, DC, 20008-2433, US

(21) Appl. No.: 10/718,972

(22) Filed: Nov. 22, 2003

(51) Int. Cl. G06F 17/00; H03M 1/66

(52) U.S. Cl. 700/94; 341/144

(57) ABSTRACT

In the digital-to-analog conversion of an audio signal, a digital audio signal that comprises a plurality of digitally quantized samples of an audio stream is received. The digital audio signal is evaluated to convert the digitally quantized samples into analog samples, and an analog audio signal is generated to contain the analog samples and correspond to the audio stream. Current-to-voltage conversion is performed on the analog audio signal. The digital audio signal can be evaluated absent oversampling. Also, electrical DC power can be chemically generated, such as by a battery, to power one or more of the evaluation of the digital audio signal, generation of the analog audio signal, or current-to-voltage conversion of the analog audio signal.

### BACKGROUND

Embodiments of the invention relate to the conversion of a digital audio signal to an analog audio signal.

Audio content can be encoded in an electronic audio signal in a digital or analog form. In the coupling of a digital audio device that outputs a digital audio signal to an analog audio device that receives an analog audio signal, the outputted digital audio signal from the digital audio device must be converted to a corresponding analog audio signal for the analog audio device. In one illustrative example, a compact disc (CD) player generates a digital audio signal representing an audio stream encoded on a CD source medium. The digital audio signal is converted into a corresponding analog audio signal, which can then be fed to an analog electronic device, such as an analog amplifier or to a loudspeaker, to acoustically reproduce the audio stream.

The conversion of the electronic audio signal from the digital form to the analog form can be carried out by a digital-to-analog audio converter (DAC). Typically, the DAC receives a digital audio signal that is discretely quantized into amplitude samples that are distributed over time at a predetermined sampling rate. The DAC reconstructs the quantized amplitude samples into an analog audio signal. Unfortunately, the reconstruction creates repetitive, high-frequency “alias” images in the analog audio signal that are a result of the finite sampling rate. Therefore, a lowpass filter is used to attempt to remove these alias images in the region above the audible range (i.e., above approximately about 20 kHz). Because the first alias image typically begins around 24 kHz, the lowpass filter is often selected to attenuate steeply between about 20 kHz and about 24 kHz in an attempt to achieve good magnitude response.

However, the sensitive analog audio signal that is outputted by the DAC is distorted because the real action of a physically implemented lowpass filter nevertheless deviates from a mathematically idealized “brickwall” filter (i.e., infinite slope in frequency space). For example, higher audible frequencies are typically attenuated by the lowpass filtering because of undesirable and concomitant filtering in the audible range (at less than about 20 kHz). Furthermore, the alias images are not perfectly filtered out because of the imperfect physical implementation of the lowpass filtering. Finally, extremely steep analog filtering adds considerable shifts in the phase response, resulting in poor representation of harmonically complex waveforms.

Conventional DACs attempt to improve the lowpass filtering by carrying out the lowpass filtering in the digital domain, known as “oversampling”. In this process, sampling points at higher than the original sampling rate are digitally interpolated, resulting in an upward shift of alias images in frequency space, in theory-allowing a slower attenuation that decreases the attenuation of audible high frequencies. Unfortunately, the denser digital datastream produced by oversampling is more susceptible to timing errors, referred to as “jitter,” in the digital data path. Jitter occurs due to, for example, imperfect transmission properties of the electrical path. When a dense digital datastream is received for conversion into an analog audio signal, jitter can cause one or more bits of the digital datastream to be misevaluated.

A further problem with conventional DACs is interference in the audio signal caused by ripple in the electrical power supplied to the DAC. Typically, the DAC comprises a power supply that rectifies AC power into roughly steady DC power for use by electronic components of the DAC. However, residual fluctuations in the rectified power, referred to as ripple, are transmitted into the audio signal as induced interference, or filter into the waveform through the amplifier circuits because no device has perfect rejection of power supply ripple. For example, for AC power having a frequency of 60 Hz, the rectified DC power may contain distortion comprising harmonics of 60 Hz. These fluctuations, which are within the audible frequency range, can cause harmonic and inharmonic distortion in the analog audio signal that is audible when the analog audio signal is acoustically reproduced.

Thus, it is desirable to convert a digital audio signal to an analog audio signal with decreased distortion from the digital-to-analog conversion process. It is further desirable to electronically generate the analog audio signal with decreased distortion caused by interference from ripples in the supplied electrical power.

### SUMMARY

A digital-to-analog audio converter comprises a non-oversampling digital-to-analog conversion stage adapted to (i) receive a digital audio signal that comprises a plurality of digitally quantized samples of an audio stream, (ii) evaluate the digital audio signal, absent oversampling, to convert the digitally quantized samples into analog samples, and (iii) generate an analog audio signal comprising the analog samples, the analog audio signal corresponding to the audio stream. An output stage performs current-to-voltage conversion of the analog audio signal and lowpass filter the analog audio signal with a corner frequency of at least about 30 kHz. Additionally, a power supply provides electrical power to one or more of the digital-to-analog conversion stage and the current-to-voltage output stage.

In another version, a digital-to-analog audio converter comprises a digital-to-analog conversion stage to convert a digital audio signal to an analog audio signal. An output stage performs current-to-voltage conversion of the analog audio signal. Additionally, a battery power supply to provide electrical power to one or more of the digital-to-analog conversion stage and the output stage, the battery power supply comprising (i) a rechargeable electrical cell, the rechargeable electrical cell being adapted to repeatedly release and acquire electrical energy, and (ii) a selector switch adapted to be set in operation such that
(a) when the selector switch is set to a first mode, the rechargeable electrical cell couples to one or more of the digital-to-analog conversion stage and the output stage, and
(b) when the selector switch is set to a second mode, the power supply couples to a power source to recharge the rechargeable electrical cell.

In yet another version, a digital-to-analog audio converter comprises a non-oversampling digital-to-analog conversion stage adapted to (i) receive a digital audio signal that comprises a plurality of digitally quantized samples of an audio stream, (ii) evaluate the digital audio signal, absent oversampling, to convert the digitally quantized samples into analog samples, and (iii) generate an analog audio signal comprising the analog samples and corresponding to the audio stream. An output stage performs current-to-voltage conversion of the analog audio signal. Additionally, a battery power supply comprising a battery provides electrical power to one or more of the digital-to-analog conversion stage and the output stage.

A method of converting a digital audio signal to an analog audio signal comprises receiving a digital audio signal that comprises a plurality of digitally quantized samples of an audio stream. The digital audio signal is evaluated, absent oversampling, to convert the digitally quantized samples into analog samples. An analog audio signal comprising the analog samples is generated to correspond to the audio stream. Current-to-voltage conversion of the analog audio signal is performed, and the analog audio signal is lowpass filtered with a corner frequency of at least about 30 kHz.

In another version, a method of converting a digital audio signal to an analog audio signal comprises
(a) receiving a digital audio signal that comprises a plurality of digitally quantized samples of an audio stream;
(b) evaluating the digital audio signal to convert the digitally quantized samples into analog samples;
(c) generating an analog audio signal comprising the analog samples, the analog audio signal corresponding to the audio stream;
(d) performing a current-to-voltage conversion of the analog audio signal;
(e) providing a rechargeable electrical cell adapted to repeatedly release and acquire electrical energy; and
(f) selecting
   (i) a first mode to perform one or more of (b), (c), and (d) under the electrical power of the rechargeable electrical cell, and
   (ii) a second mode to couple a power source to the rechargeable electrical cell to recharge the rechargeable electrical cell.

In yet another version, a method of converting a digital audio signal to an analog audio signal comprises
(a) receiving a digital audio signal that comprises a plurality of digitally quantized samples of an audio stream;
(b) evaluating the digital audio signal, absent oversampling, to convert the digitally quantized samples into analog samples;
(c) generating an analog audio signal comprising the analog samples, the analog audio signal corresponding to the audio stream;
(d) performing a current-to-voltage conversion of the analog audio signal; and
(e) chemically generating direct-current electrical power to power one or more of (b), (c), and (d).

### DRAWINGS

These features, aspects, and advantages of the present invention will become better understood with regard to the following description, appended claims, and accompanying drawings, which illustrate versions of the invention, where:

FIG. 1 is a block diagram of an embodiment of a digital-to-analog audio converter;

FIG. 2 is a graph showing overlapping plots of (i) an embodiment of an original audio stream, (ii) digital samples of a digital audio signal corresponding to the original audio stream, (iii) a pulse-amplitude modulated waveform corresponding to the digital samples, and (iiii) an analog audio signal resulting from digital-to-analog conversion of the digital audio signal, plotted in magnitude as a function of time; and

FIG. 3 is a graph showing an embodiment of overlapping plots of (i) the audible band, (ii) alias images corresponding to the content in the audible band, (iii) a high attenuation rate, and (iv) a low attenuation rate, plotted in magnitude (dB) as a function of frequency (Hz).

### DESCRIPTION

Digital-to-analog audio conversion is performed on a digital audio signal that corresponds to an audio stream recorded on a source medium to convert the digital audio signal into an analog audio signal. For example, the digital-to-analog (D/A) conversion may be used to bridge a signal path between an audio device that reads the source medium to output a digital audio signal and an audio device that receives an analog audio signal to modify or reproduce the analog audio signal. Audio devices that can output a digital audio signal include, for example, compact disc (CD) players, digital audio tape (DAT) players, minidisc (MD) players, personal computers, and MPEG-3 players. Audio devices that receive an analog audio signal include, for example, amplifiers, recording devices, loudspeakers, and electronic switches.

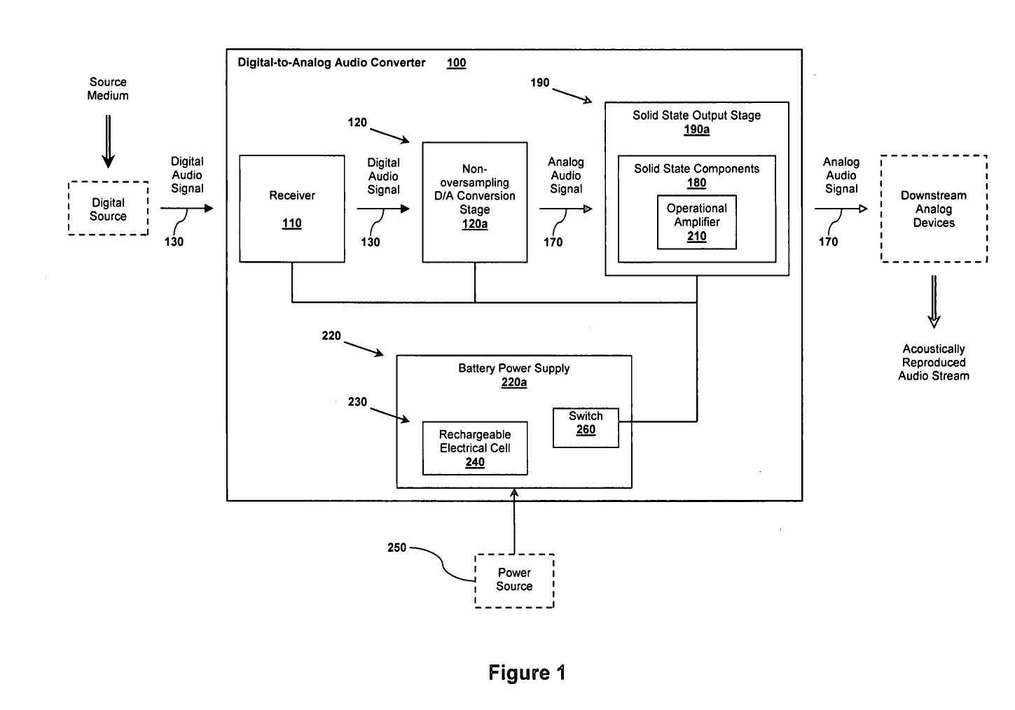

A digital-to-analog audio converter (DAC) 100, as illustrated in FIG. 1, is an apparatus that is adapted to perform conversion of a digital audio signal to an analog audio signal. One embodiment of the digital-to-analog audio converter 100, which is shown in the Figure, is a “dAck!™” digital-to-analog audio converter 100 fabricated by AckIndustries™, Evanston, Ill. The DAC 100 of FIG. 1 is provided only to illustrate the invention and should not be used to limit the scope of the invention or its equivalents to the exemplary embodiments provided herein.

The digital-to-analog audio converter 100 may comprise a receiver 110 to modify an incoming digital audio signal 130 from a digital source. For example, the receiver 110 may extract a clock signal from the digital audio signal. Also, if the digital audio signal is a multiplexed digital audio signal comprising audio streams on a plurality of distinct channels, the receiver 110 can demultiplex the digital audio signal to physically separate the multiple channels. In one embodiment, the receiver 110 is adapted to demultiplex the digital audio signal into two channels to reconstruct stereo audio. However, the receiver 110 may otherwise be adapted to demultiplex the digital audio signal into any number of channels, such as three channels or five channels. In addition, the receiver 110 may be adapted to perform sampling rate conversion.

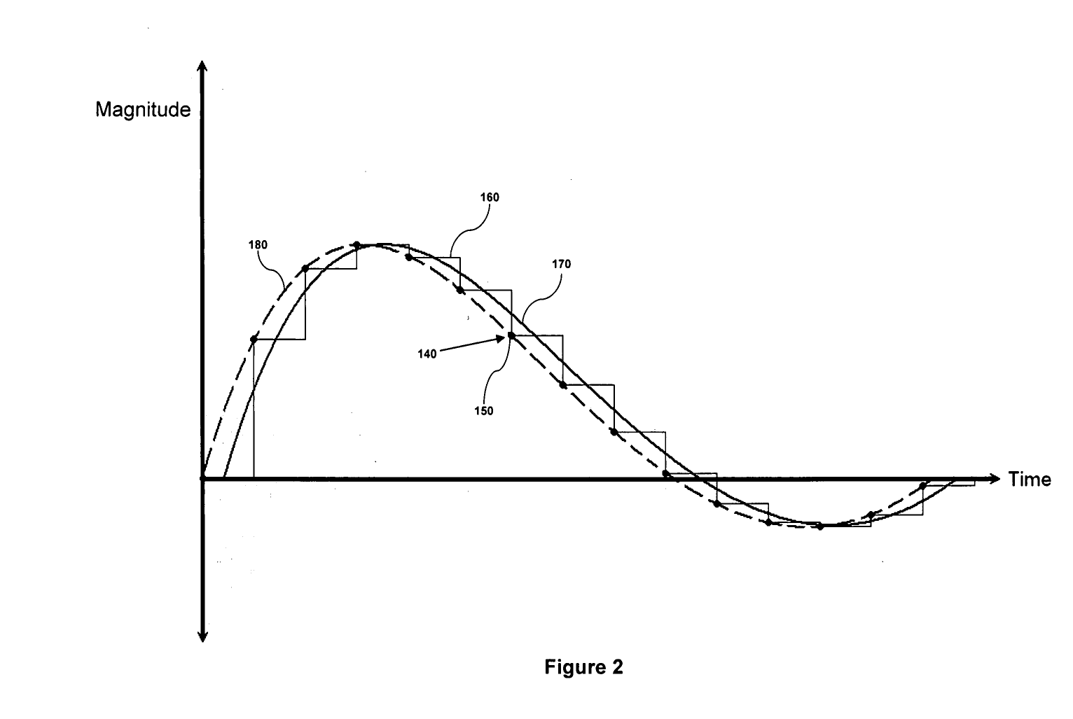

The digital-to-analog audio converter 100 comprises a digital-to-analog conversion stage 120 to receive a digital audio signal 130 that comprises a plurality of digitally quantized samples 140 (as shown in FIG. 2) of an original audio stream 180. For example, as illustrated in FIG. 1, the digital-to-analog conversion stage 120 may receive the digital audio signal 130 from the receiver 110. Each digital sample 140 is typically in the form of a “word” comprising a predetermined number of binary bits. For example, a single digital sample 140 may comprise 16 bits, allowing a quantization resolution of 65,536 levels. The number of digitally quantized samples 140 in a unit of time is the rate at which the audio stream 180 was sampled. For example, the sampling rate of the digitally quantized samples 140 may be at least about 44.1 kHz to adequately capture substantially the entire audible frequency band.

The digital audio signal 130 is evaluated by the digital-to-analog conversion stage 120 to convert the digitally quantized samples 140 into analog samples 150, an embodiment of which is illustrated in FIG. 2. For example, the digital-to-analog conversion stage 120 may comprise a digital-to-analog converter integrated circuit chip (not shown) to perform the main D/A conversion. Typically, a pulse-amplitude modulated (PAM) waveform 160 is generated. For example, a sample-and-hold procedure may be carried out on the analog samples 150 to generate the PAM waveform 160 to have magnitude steps at the intensity values of the analog samples 150. The digital-to-analog conversion stage 120 may also perform further processing in either the analog or digital domain to generate a desirable analog audio signal 170. Within the audible range, the resulting analog audio signal 170 yields a better approximation to the original audio stream 180 recorded on the source medium than a conventional oversampling DAC.

Returning to FIG. 1, in one version the D/A conversion stage 120 is a non-oversampling D/A conversion stage 120a that outputs the values of the digitally quantized samples 140 of the digital audio signal 130, absent oversampling of the digital audio signal 130, as analog samples 150 in the analog audio signal 170. Oversampling refers to periodic insertion into the digital audio signal 130 of additional quantized digital samples (not shown) that are not samples recorded on the source medium. These inserted samples are interpolated or otherwise determined based on the original digital samples 140 of the audio stream 180. When oversampling, which also includes methods referred to as “upsampling,” a pattern of interpolated samples is inserted at a periodic rate that is an integer or non-integer multiple of the sampling rate of the original audio stream recorded on the source medium, having the effect of lowpass filtering the digital audio signal 130 in the digital domain.

Converting the digital audio signal 130 to an analog audio signal 170 absent oversampling removes distortion from the analog audio signal 170. Reconstructing the analog audio signal 170 at the real sampling rate rather than a periodic higher artificial sampling rate substantially decreases the amount of distortion that is introduced into the analog audio signal 170. For example, the lower frequency of the non-oversampled digital audio signal 130, in comparison to the higher frequency of an oversampled digital audio signal, allows the non-oversampled conversion process to be less susceptible to jitter. It is believed that maximum jitter is approximately inversely exponentially related to datastream density, and thus a datastream of reduced density is considerably less sensitive to jitter. Alleviating the jitter in the digital audio signal 130 decreases distortion in the analog audio signal 170.

Furthermore, the lower frequency content of the non-oversampled digital audio signal 130 can reduce radio frequency interference (RFI) caused in neighboring electronic circuits by the digital audio signal 130 and thereby further reduce distortion. In contrast, higher oversampled frequency content increases the likelihood of induced current generation between adjacent electronic circuits, such as circuits in downstream amplification equipment, causing greater interference in the signals conveyed by these circuits. In one example, the non-oversampled digital audio signal 130 has a main frequency range with an upper bound of about 44.1 kHz.

The D/A conversion stage 120 may further be adapted to perform error correction on the digital audio signal 130. This may comprise, for example, redundancy analysis of the digital audio signal 130 to identify and correct erroneous digital samples. The error correction procedure may also comprise aperiodic interpolation of erroneous digital samples whose original values are unrecoverable through redundancy analysis. The error-corrected digital audio is subsequently evaluated by the D/A conversion stage 120 to generate the analog audio signal 170. Error correction improves the accuracy of the eventual analog audio signal 170 by minimizing the damage caused by errors in the digital audio signal 130.

The digital-to-analog converter 100 further comprises an output stage 190 to receive the analog audio signal 170 from the D/A conversion stage 120 and perform current-to-voltage conversion of the analog audio signal 170. Generally, the output stage 190 has an input impedance of a first value and an output impedance of a second value, the second value being substantially less than the first value. The analog audio signal 170 may carry the evaluated magnitude of the digital sample 140 as an electrical current value at a weak voltage. The output stage 190 receives the current representing an output signal from the D/A conversion stage 120 and outputs a usable voltage whose magnitude corresponds to this output signal. In other words, the output stage 190 causes the voltage to be the main signal-carrying component of the analog audio signal 170. The output stage 190 adjusts the voltage or current magnitude to a level that is suitable to be received by electronic analog devices downstream of the DAC 100. For example, the output stage 190 may amplify the analog audio signal 170 to a predetermined voltage amplitude.

The output stage 190 has an output impedance selected to couple the output stage 190 to analog electronic devices downstream of the DAC 100. For example, the output stage 190 may have a low output impedance selected to be less than about 1.5 kOhm. This limits the drop in voltage across the downstream analog devices as outputted current from the output stage 190 increases, allowing predictable coupling between the output stage 190 and these downstream analog devices.

In one version, the output stage 190 is a solid state output stage 190a comprising one or more solid state electronic components 180 and absent valve (tube) components. The solid state electronic components 180 are electrically active semiconductor-based components, such as components based on silicon or other semiconductor materials. The solid state output stage 190a is capable of producing a voltage from the output signal with a suitably fast response time while substantially preserving the audio information in the output signal. In contrast, a valve (tube) output stage typically has a slow response time and can cause an undesirable amount of harmonic distortion. Additionally, a solid state output stage 190a has a low power supply rejection ratio in comparison to a valve output stage (not shown) and is less sensitive to electromagnetic interference. The solid state electronic components 180 are adapted to receive electrical power and use the electrical power to enable the current-to-voltage conversion of the analog audio signal that is transmitted through the solid state electronic components 180. For example, the solid state electronic components 180 may comprise an operational amplifier (op-amp) 210 to amplify the analog audio signal 170.

The solid state output stage 190a may be adapted to operate in a constantly-biased mode to improve linearity. Referred to as “class A,” this mode prevents distortion due to the switching on and off of components in the output stage 190a. For example, if an op-amp 210 of the solid state output stage 190a swings between positive and negative voltage at the output, there is a region near zero where output devices in the op-amp are inactive, thereby distorting the amplified signal that is outputted. By keeping the output of the op-amp 210 biased, and therefore active with current passing through the op-amp 210, this switching distortion is avoided. Thus, constantly biasing the solid state output stage 190a can improve the linearity of its response.

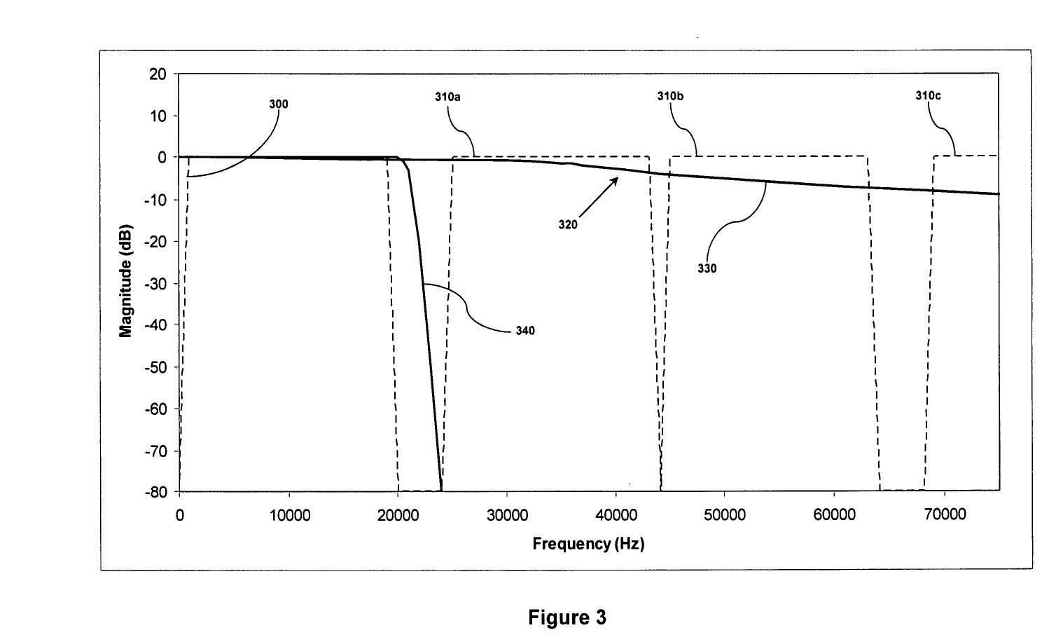

Furthermore, as illustrated in the example graph of FIG. 3, the analog audio signal 170 may be lowpass filtered to attenuate alias images 310a-c at frequencies above a preselected corner frequency 320 and at a preselected attenuation rate 330. For example, the solid state output stage 190a may be adapted to perform active lowpass filtering in addition to current-to-voltage conversion. In one embodiment, the active filtering is brought about by inclusion of a capacitor in a feedback loop of the solid state output stage 190a. Providing an active analog lowpass filter typically results in improved output impedance, higher accuracy, and smaller size when compared with a passive analog lowpass post-filter. Additionally, an active filter can be configured to amplify the analog audio signal 170.

The analog audio signal 170 may be lowpass filtered with a corner frequency 320 of at least about 30 kHz to pass a substantial portion of the first alias image 310a corresponding to a sampling rate of about 44.1 kHz while attenuating higher-frequency alias images 310b,c. For example, the analog audio signal 170 may be lowpass filtered with a corner frequency 320 of at least about 41 kHz, as shown in FIG. 3. The first alias image 310a, corresponding to a sampling rate of about 44.1 kHz, begins at about 24 kHz and ends at about 44 kHz. In one version, the solid state output stage 190a is adapted to perform the lowpass filtering around this preselected corner frequency 320. Certain amplifiers may undesirably intermodulate harmonic content above a particular frequency into the audible band 300. For example, older amplifiers or push-pull amplifiers may intermodulate frequencies above 44 kHz into the audible band 300 of from about 20 Hz to about 20 kHz. Meanwhile, frequencies of from about 20 kHz to about 44 kHz may pass through these amplifiers substantially absent any intermodulation. In contrast, newer or single-ended amplifiers may pass frequencies above at least about 44 kHz substantially absent intermodulation. Thus, lowpass filtering the analog audio signal 170 from at least about 30 kHz can be advantageous for compatibility with various diverse types of amplifiers, such as for backward compatibility with older amplifiers.

Moreover, the analog audio signal 170 may be lowpass filtered at a low slope (as graphically represented in frequency space, i.e., a small decrease in amplitude with increasing frequency) to prevent undesirable attenuation of certain high frequencies in the audible band 300. In one version, the solid state output stage 190a is adapted to perform the lowpass filtering at the preselected low attenuation rate 330. An attenuation rate 330 of less than about 80 dB/decade can be selected such that frequencies below the corner frequency 320 are substantially unaffected while frequencies above the corner frequency 320 are gently attenuated. In a further example, the solid state output stage 190a attenuates the analog audio signal 170 at a rate 330 of less than about 20 dB/decade. The low slope of the filtering passes the lower-frequency alias images while attenuating the higher-frequency alias images with low phase error. In contrast, a high attenuation rate (i.e., high slope) 340 largely removes the lower-frequency alias images, such as most of the first alias image 310a.

Further along the signal chain, as shown in FIG. 1, the audio signal may be filtered of frequencies above the audible range by downstream analog devices. For example, the analog devices may include loudspeakers or amplifiers. The analog devices may substantially filter frequencies of at least about 21 kHz, or even of at least about 24 kHz, in order to substantially prevent the transmission of these ultrasonic frequencies. Thus, the DAC 100 is able to transmit frequencies above the audible range while maintaining substantial integrity of the audio signal within the audible frequency range.

After the analog audio signal traverses the analog devices between the DAC 100 and a human listener, the analog audio signal may still contain frequencies above the audible band 300. These ultrasonic frequencies are, in effect, filtered out of the perceived audio signal by human acoustic response, substantially absent any intermodulation. These ultrasonic frequencies substantially do not interfere with the audible portion of the audio signal. Thus, even residual ultrasonic frequency content that is not entirely removed by the post-DAC analog devices does not substantially affect the high-quality audibly perceived portion of the acoustically reproduced audio stream.

The digital-to-analog audio converter 100 further comprises a power supply 220 to supply electrical power to the electrical components of the DAC 100. For example, the power supply 220 may provide direct-current (DC) power to one or more of the digital-to-analog conversion stage 120 and the output stage 190. The power supply 220 provides a DC power having a voltage and a current that are preselected to be suitable for one or more of the digital-to-analog conversion stage 120 and the output stage 190.

In one version, the power supply 220 is a battery power supply 220a comprising a battery 230 to provide stable direct-current power and thereby reduce distortion in the analog audio signal 170. The battery 230 is an electrical cell that provides electrical power through a chemical reaction. The electrical power is of suitable voltage and current to drive one or more of the D/A conversion stage 120 and the output stage 190. One or more of (i) evaluation of the digital audio signal 130, (ii) generation of the analog audio signal 170, and (iii) current-to-voltage conversion of the analog audio signal 170 are performed under the electrical power of the battery power supply 220a. The battery power supply 220a obviates the need for rectification of received alternating-current (AC) power by chemically generating low-ripple DC power.

The battery power supply 220a may comprise a battery 230 that is a rechargeable electrical cell 240 to electrically power one or more of the D/A conversion stage 120 and the output stage 190. The rechargeable electrical cell 240 is adapted to repeatedly store and release electrical energy in the form of chemical potential energy. To store energy, the rechargeable electrical cell 240 receives electrical power from a power source 250 through a cathode electrode and an anode electrode. The rechargeable electrical cell 240 undergoes a chemical reaction that accumulates the electrical power as chemical potential energy. To release energy, the rechargeable electrical cell 240 undergoes a reverse chemical reaction that causes current to flow through a circuit connected between the cathode electrode and the anode electrode of the rechargeable electrical cell 240.

In one embodiment, the rechargeable electrical cell 240 comprises a sealed lead-acid battery. A sealed lead-acid battery has electrodes that comprise lead. In one example, at a positive electrode, lead dioxide (PbO₂) is converted to lead sulfate (PbSO₄) and, at a negative electrode, sponge metallic lead (Pb) is also converted to lead sulfate (PbSO₄). The electrolyte surrounding the electrodes is a dilute mixture of sulfuric acid that provides the sulfate ion for the discharge reactions. The sealed lead-acid battery is capable of providing a substantially steady current with ultra-low noise in comparison with many other batteries. Additionally, the sealed lead-acid battery can provide a large, substantially instantaneous “burst” current when such bursts are required by the audio signal. For example, a small rechargeable electrical cell 240 may be capable of providing several dozen Amperes of burst current, such as a burst current of at least about 7.5 A. Furthermore, the sealed lead-acid battery can provide the above advantages at a lower cost than many alternative batteries.

In an alternative embodiment, the rechargeable electrical cell 240 comprises a lithium ion cell. The lithium ion cell can provide long operational lifetime with short cyclic operation. In yet another embodiment, the rechargeable electrical cell 240 comprises a nickel cadmium (NiCad) cell. The NiCad cell can provide a cost-effective battery solution for deep discharge applications. In still another possible embodiment, the rechargeable electrical cell 240 comprises a nickel metal hydride (NiMH) cell. The NiMH cell can provide a combination of high energy capacity and high current.

In one version, the battery power supply 220a is a dual-mode power supply capable of switching between a first “charge” mode and a second “play” mode. This battery power supply 220a is adapted to, in the first (charge) mode, receive electrical energy and store the electrical energy as chemical potential energy for later use. In the second (play) mode, the battery power supply 220a is adapted to retrieve the chemical potential energy through a chemical reaction and release the chemical potential energy as electrical energy for use by one or more of the D/A conversion stage 120 and the output stage 190.

The DAC 100 may comprise a selector switch 260 that is adapted to switch between the first and second modes to re-route power to or from the rechargeable electrical cell 240. The switch 260 is adapted to be set in operation such that when the selector switch is set to a first mode, the rechargeable electrical cell 240 couples to one or more of digital-to-analog conversion stage and current-to-voltage output stage to allow digital-to-analog conversion. When the switch 260 is set to a second mode, the battery power supply 220a couples to a power source 250 to recharge the rechargeable electrical cell 240. The power source 250 may comprise a source of AC power that is external to the DAC 100, such as an electrical outlet.

In one example, the DAC 100 comprises a selector switch 260 that is a manual switch to allow a human operator to switch the battery power supply 220a between the first and second modes. When a mode is selected, this manual switch re-routes electricity such that the rechargeable electrical cell 240 charges in the first mode and discharges in the second mode. For example, the switch 260 may comprise a toggle switch, depressable button, rotatable knob, knife switch, or sliding switch. The DAC 100 may also comprise a visual indicator (not shown) adapted to visually indicate to a human operator whether the selector switch 260 is presently in the first mode or the second mode. The visual indicator may comprise, for example, a light-emitting diode, incandescent bulb, or liquid crystal display.

Alternatively to the manual switch, the switch 260 of the DAC 100 may be a “smart” switch adapted to automatically switch between the first “charge” mode and the second “play” mode in at least one direction. In one exemplary embodiment, the smart switch is adapted to sense the presence of an incoming signal received by the digital-to-analog conversion stage 120 and automatically switch from the first mode to the second mode. The smart switch can further sense the absence of the incoming signal when the DAC 100 is not in active use, and revert from the second mode to the first mode for continued charging absent intervention by a human operator. For example, the smart switch may comprise circuitry that senses a change in voltage level on an input terminal connected to the digital-to-analog conversion stage 120. When the voltage change is detected, a solid state switch or electrical relay can re-route electricity to or from the rechargeable electrical cell 240.

An alternative embodiment of the smart switch comprises a sensor circuit (not shown) that detects the condition of the rechargeable electrical cell 240 during operation and is adapted to switch to the first “charge” mode automatically when the sensor circuit indicates that the charge level of the rechargeable electrical cell 240 is below a predetermined level. In yet another embodiment, the smart switch comprises a timer circuit (not shown) that automatically switches to the first “charge” mode after a predetermined time of operation in the second “play” mode.

Returning to the subject of the power supply 220, an alternative to the battery power supply 220a may comprise an AC power supply (not shown) to rectify AC power in real-time and pass the rectified DC power directly to the rest of the DAC 100. For example, the AC power supply may comprise a transformer (not shown) and a rectifier stage. The transformer converts voltage and/or current to AC magnitudes that are adapted to be used by the D/A audio converter 100. The rectifier stage converts the AC power into DC power such that the transformed and rectified electrical power is suitable for use by the D/A audio converter 100.

The digital-to-analog audio converter 100 converts a digital audio signal into an analog audio signal with decreased distortion and consequently improved retention of important audio content in the audio signal. By converting the digital audio signal 130 to the analog audio signal 170 absent oversampling, jitter in the signal path and radio frequency interference with the audio signal are substantially alleviated to reduce distortion. By chemically generating DC electrical power for the DAC 100, such as by providing a battery power supply 220a, ripple in the power signal is decreased. Lower ripple levels result in reduced distortion in the final analog audio signal 170.

While the present invention has been described in considerable detail with reference to certain preferred versions, many other versions should be apparent to those of ordinary skill in the art. For example, the digital-to-analog audio converter 100 may be adapted to convert a digital audio signal 130 of any bit-length or sampling rate. Therefore, the spirit and scope of the appended claims should not be limited to the description of the preferred versions contained herein.

1. A digital-to-analog audio converter comprising:
a non-oversampling digital-to-analog conversion stage adapted to
(i) receive a digital audio signal that comprises a plurality of digitally quantized samples of an audio stream,
(ii) evaluate the digital audio signal, absent oversampling, to convert the digitally quantized samples into analog samples, and
(iii) generate an analog audio signal comprising the analog samples, the analog audio signal corresponding to the audio stream;
an output stage to perform current-to-voltage conversion of the analog audio signal and lowpass filter the analog audio signal with a corner frequency of at least about 30 kHz; and
a power supply to provide electrical power to one or more of the digital-to-analog conversion stage and the current-to-voltage output stage.

2. A digital-to-analog audio converter according to claim 1 wherein the output stage is adapted to lowpass filter the analog audio signal at an attenuation rate of less than about 80 dB/decade.

3. A digital-to-analog audio converter according to claim 1 wherein the output stage is a solid state output stage comprising a solid state electronic component.

4. A digital-to-analog audio converter according to claim 3 wherein the solid state output stage is adapted to operate in a continuously-biased mode.

5. A digital-to-analog audio converter according to claim 3 wherein the solid state output stage has an output impedance of less than about 1.5 kOhm.

6. A digital-to-analog audio converter comprising:
a digital-to-analog conversion stage to convert a digital audio signal to an analog audio signal;
an output stage to perform current-to-voltage conversion of the analog audio signal; and
a battery power supply to provide electrical power to one or more of the digital-to-analog conversion stage and the output stage, the battery power supply comprising
(i) a rechargeable electrical cell, the rechargeable electrical cell being adapted to repeatedly release and acquire electrical energy, and
(ii) a selector switch adapted to be set in operation such that
(a) when the selector switch is set to a first mode, the rechargeable electrical cell couples to one or more of the digital-to-analog conversion stage and the output stage, and
(b) when the selector switch is set to a second mode, the power supply couples to a power source to recharge the rechargeable electrical cell.

7. A digital-to-analog audio converter according to claim 6 wherein the rechargeable electrical cell comprises a sealed lead-acid battery.

8. A digital-to-analog audio converter comprising:
a non-oversampling digital-to-analog conversion stage adapted to
(i) receive a digital audio signal that comprises a plurality of digitally quantized samples of an audio stream,
(ii) evaluate the digital audio signal, absent oversampling, to convert the digitally quantized samples into analog samples, and
(iii) generate an analog audio signal comprising the analog samples, the analog audio signal corresponding to the audio stream;
an output stage to perform current-to-voltage conversion of the analog audio signal; and
a battery power supply, the battery power supply comprising a battery, to provide electrical power to one or more of the digital-to-analog conversion stage and the output stage.

9. A digital-to-analog audio converter according to claim 8 wherein the output stage is a solid state output stage.

10. A digital-to-analog audio converter according to claim 8 wherein the battery comprises a rechargeable electrical cell, the rechargeable electrical cell being adapted to repeatedly release and acquire electrical energy.

11. A digital-to-analog audio converter according to claim 10 wherein the battery power supply comprises a selector switch adapted to be set in operation such that
(i) when the selector switch is set to a first mode, the battery power supply couples to one or more of the digital-to-analog conversion stage and the output stage, and
(ii) when the selector switch is set to a second mode, the battery power supply couples to a power source to recharge the rechargeable electrical cell.

12. A method of converting a digital audio signal to an analog audio signal, the method comprising:
(a) receiving a digital audio signal that comprises a plurality of digitally quantized samples of an audio stream;
(b) evaluating the digital audio signal, absent oversampling, to convert the digitally quantized samples into analog samples;
(c) generating an analog audio signal comprising the analog samples, the analog audio signal corresponding to the audio stream;
(d) performing current-to-voltage conversion of the analog audio signal; and
(e) lowpass filtering the analog audio signal with a corner frequency of at least about 30 kHz.

13. A method according to claim 12 wherein (e) comprises lowpass filtering the analog audio signal at an attenuation rate of less than about 80 dB/decade.

14. A method according to claim 12 wherein (d) comprises transmitting the analog audio signal through a solid state electronic component.

15. A method according to claim 14 wherein (d) comprises performing current-to-voltage conversion of the analog audio signal in a continuously-biased mode.

16. A method of converting a digital audio signal to an analog audio signal, the method comprising:
(a) receiving a digital audio signal that comprises a plurality of digitally quantized samples of an audio stream;
(b) evaluating the digital audio signal to convert the digitally quantized samples into analog samples;
(c) generating an analog audio signal comprising the analog samples, the analog audio signal corresponding to the audio stream;
(d) performing a current-to-voltage conversion of the analog audio signal;
(e) providing a rechargeable electrical cell adapted to repeatedly release and acquire electrical energy; and
selecting
(i) a first mode to perform one or more of (b), (c), and (d) under the electrical power of the rechargeable electrical cell, and
(ii) a second mode to couple a power source to the rechargeable electrical cell to recharge the rechargeable electrical cell.

17. A method according to claim 16 wherein (e) comprises providing a sealed lead-acid battery.

18. A method of converting a digital audio signal to an analog audio signal, the method comprising:
(a) receiving a digital audio signal that comprises a plurality of digitally quantized samples of an audio stream;
(b) evaluating the digital audio signal, absent oversampling, to convert the digitally quantized samples into analog samples;
(c) generating an analog audio signal comprising the analog samples, the analog audio signal corresponding to the audio stream;
(d) performing a current-to-voltage conversion of the analog audio signal; and
(e) chemically generating direct-current electrical power to power one or more of (b), (c), and (d).

19. A method according to claim 18 wherein (d) comprises transmitting the analog audio signal through a solid state electronic component.

20. A method according to claim 18 wherein (e) comprises providing a rechargeable electrical cell adapted to repeatedly release and acquire electrical energy.

21. A method according to claim 20 further comprising selecting
(i) a first mode to perform one or more of (a), (b), and (d) under the electrical power of the rechargeable electrical cell, and
(ii) a second mode to couple a power source to the rechargeable electrical cell to recharge the rechargeable electrical cell.
